(19) United States
(12) Patent Application Publication
(10) Pub. No.: US 2015/0086716 A1
(43) Pub. Date: Mar. 26, 2015

(54) PRINTING OF COLORED PATTERN USING ATOMIC LAYER DEPOSITION

(71) Applicant: Veeco ALD Inc., Fremont, CA (US)

(72) Inventors: Samuel S. Park, San Ramon, CA (US); Hyo-Seok Yang, Cupertino, CA (US); Sang In Lee, Los Altos Hills, CA (US)

(21) Appl. No.: 14/494,294

(22) Filed: Sep. 23, 2014

Related U.S. Application Data
(60) Provisional application No. 61/883,095, filed on Sep. 26, 2013.

(51) Int. Cl. C23C 16/04; C23C 16/00

(52) U.S. Cl. CPC C23C 16/04; C23C 16/006
USPC 427/255.28; 118/720

(57) ABSTRACT

An apparatus for depositing a layer of material at different thicknesses on a substrate using atomic layer deposition (ALD) to form patterns that exhibit different colors. The patterns may be formed using a printer head that moves in a two-dimensional plane over the substrate along a path while injecting the precursor gases onto the substrate. Patterns are formed on the substrate along the path along which the printer head moves. The refraction of light incident on the layer of material on the substrate causes the deposited material to exhibit different colors. The color change is caused by thin-film interference caused by interference with light waves reflected by the upper and lower boundaries of the deposited material

### CROSS-REFERENCE TO RELATED APPLICATIONS

This application claims priority under 35 U.S.C. §119(e) to co-pending U.S. Provisional Patent Application No. 61/883,095, filed on Sep. 26, 2013, which is incorporated by reference herein in its entirety.

### BACKGROUND

1. Field of Art

The disclosure relates to forming a layer of material on a substrate using a printer head that performs atomic layer deposition (ALD) on the substrate.

2. Description of the Related Art

Instead of using conventional semiconductor manufacturing processes, substrates for electronic devices may also be printed with various patterns using various types of materials. Common printing equipments may be used to print ink or other materials on selected areas of the substrate. The printing of patterns is not limited solely to decorative or ornamental features on the substrate, and sometimes printing may be used to form electronic components such as thin film transistor (TFT) or resistors. The process of printing components or features generally has the advantage of producing high-precision components at a low cost.

Atomic layer deposition (ALD) is one way of depositing material on a substrate. ALD uses the bonding force of a chemisorbed molecule that is different from the bonding force of a physisorbed molecule. In ALD, source precursor is adsorbed onto the surface of a substrate and then purged with an inert gas to remove physisorbed molecules of the source precursor while retaining chemisorbed molecules of the source precursor on the substrate. As a result, physisorbed molecules of the source precursor (bonded by the Van der Waals force) are desorbed from the substrate. However, chemisorbed molecules of the source precursor are covalently bonded, and hence, these molecules are strongly adsorbed in the substrate and not desorbed from the substrate.

The chemisorbed molecules of the source precursor (adsorbed on the substrate) react with and/or are replaced by molecules of reactant precursor. Then, the excessive precursor or physisorbed molecules are removed by injecting the purge gas and/or pumping the chamber, obtaining a final atomic layer.

### SUMMARY

Embodiments relate to printing a pattern on a substrate by using a printer head that injects source precursor and reactant precursor onto the substrate. On areas of the substrate exposed to both the source precursor and the reactant precursor, a layer of material forms the pattern by atomic layer deposition (ALD). A first actuator causes the printer head to move along a first axis parallel to a surface of the substrate. A second actuator causes the printer head to move along a second axis parallel to the surface of the substrate. The movement of the printer head by the first and second actuatord deposits the pattern on the substrate. A conduit is connected to the printer head to provide the source precursor and the reactant precursor to the printer head.

In one embodiment, a controller controls at least a parameter associated with a thickness of the layer of the material deposited on the substrate.

In one embodiment, different portions of the pattern exhibit different colors based on the different thickness of the layer of material.

In one embodiment, a third actuator causes the printer head to move towards or away from the substrate.

In one embodiment, the printer head injects purge gas onto the substrate to remove at least excess source precursor from the surface of the substrate. The purge gas is provided by the conduit.

In one embodiment, the printer head includes a body. The body is formed with a first injection chamber for injecting the source precursor onto the substrate, and a second injection chamber surrounding the first injection chamber. The second injection chamber injects the reactant precursor onto the substrate.

In one embodiment, the body is further formed with a channel, a first exhaust and a second exhaust. The channel is open towards the substrate to inject purge gas onto the substrate. The channel is formed between the first injection chamber and the second injection chamber. The first exhaust formed between the first injection chamber and the channel discharges excess source precursor not chemisorbed on the substrate. The second exhaust formed between the channel and the second injection chamber discharges at least excess reactant precursor not chemisorbed on the substrate.

In one embodiment, the body is formed with a first constriction zone and a second constriction zone. The first constriction zone is formed for connecting the first exhaust and the first injection chamber. The first constriction zone has a height smaller than a width of the first injection chamber. The second constriction zone is formed for connecting the second exhaust and the second injection chamber. The second constriction zone has a height smaller than a width of the second injection chamber.

Embodiments also relate to a printer head assembly including a printer head and a conduit. The printer head includes a body formed with a first injection chamber and a second injection chamber. The first injection chamber injects first gas onto a substrate. The second injection chamber surrounds the first injection chamber and injects second gas onto the substrate. The second gas reacts or replaces molecules of the first gas adsorbed on the substrate to form a layer of material on the substrate. The conduit is connected to the printer head to provide the first gas and the second gas to the printer head.

Embodiments also relate to a method of forming a pattern on a substrate. Source precursor is injected onto a surface of a substrate via a printer head. Reactant precursor is injected onto the surface via the printer head. The printer head is moved along a path on a substrate while controlling at least a parameter associated with a thickness of layer deposited on the substrate by reaction or replacement of molecules of the source precursor with molecules of the reactant precursor on the surface. Excess source precursor and reactant precursor from the surface of the substrate are discharged via the printer head. Deposition rate of the film can be changed by controlling how

### BRIEF DESCRIPTION OF DRAWINGS

Figure (FIG.) 1 is a schematic diagram of a printing device using atomic layer deposition (ALD), according to one embodiment.

FIG. 2 is a perspective view of a printer head and a conduit for providing gases to the printer head, according to one embodiment.

FIG. 3A is a cross sectional diagram of a printer head taken along line A-B of FIG. 2, according to one embodiment.

FIG. 3B is a cross sectional diagram of the printer head taken along line C-D of FIG. 2, according to one embodiment.

FIG. 4 is a cross sectional diagram of a printer head, according to another embodiment.

FIG. 5 is a top view of a substrate printed with patterns, according to one embodiment.

FIG. 6 is a cross sectional diagram of a substrate printed with material of different thicknesses to exhibit different colors, according to one embodiment.

FIG. 7 is a schematic diagram illustrating the degree of freedom for the printer head, according to one embodiment.

FIG. 8 is a flowchart illustrating a method of forming a pattern of material with different thickness, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to depositing a layer of material at different thicknesses on a substrate using atomic layer deposition (ALD) to form patterns that exhibit different colors. The patterns may be formed using a printer head that moves in a two-dimensional plane over the substrate along a path while injecting precursor gases onto the substrate. Patterns are formed on the substrate along the path along which the printer head moves. The refraction of light incident on the layer of material on the substrate causes the deposited material to exhibit different colors. The color change is caused by thin-film interference caused by interference with light waves reflected by the upper and lower boundaries of the deposited material.

Figure (FIG.) 1 is a schematic diagram of a printing device 100 using atomic layer deposition (ALD), according to one embodiment. The printing device 100 may include, among other components, a printer head 116, a conduit 120, arms 104, 108, 138 and mechanisms 130, 134, 140 for moving the arms 104, 108, 138. The printer head 116 is secured to the arm 108, which is in turn mounted on the arm 104 via a linear motor 134.

The arm 108 moves in Y-direction by the operation of an actuator such as linear motor 134 and the arm 104 moves in X-direction by the operation of another actuator such as motor 130. The arm 138 may move in Z-direction by the operation of an actuator such as linear motor 140 to change the vertical locations of the arms 104, 108 and the printer head 116. By moving the printer head 116 vertically, the location of the printer head 116 can be moved closer to the substrate 112 or moved away from the substrate 112 to adjust distance h between the printer head 116 and the substrate 112. While loading or unloading the substrate 112, the printer head 116 can be raised to facilitate the loading or unloading operation. The distance h can also be finely tuned to produce better quality deposition on the substrate 112.

As the arms 104, 108 are operated, the printer head 116 and the conduit 120 move along a path 126 in a two-dimensional plane (defined by X-direction and Y-direction) above a substrate 112, and deposits a layer of material on the substrate 112 to form a pattern 124. The path 126 may include linear segments, non-linear segments and a combination of both linear and non-linear segments. In the example of FIG. 1, the printer head 116 moves along a path 126 by the operation of the linear motor 134 and the motor 130. The linear motor 134 and the motor 130 may receive signals from a controller 150 to coordinate the movement along the path 126 and also control the speed of the printer head 116.

The conduit 120 provides gases for performing ALD on the substrate 112 to the printer head 116. The conduit 120 may be made of flexible material and includes multiple channels for separately routing the gases to the printer head 116. The conduit 120 may also include one or more channels for discharging excess materials injected onto the substrate 112. The conduit 120 may be connected to a valve assembly that controls gas flow to the conduit 120.

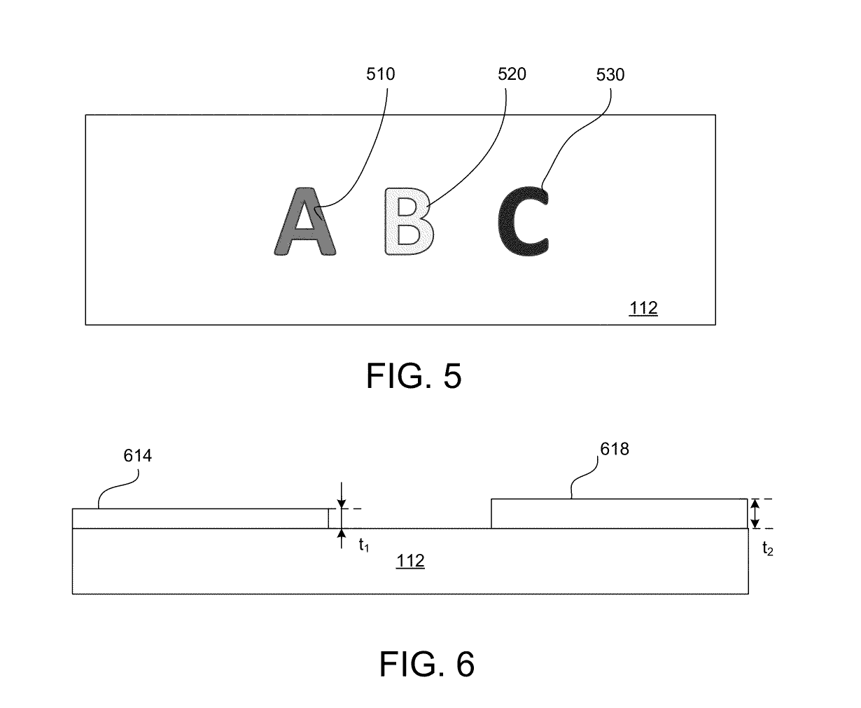

In one embodiment, a silicon substrate is used as the substrate 112, and an oxide is deposited to form the pattern 124. By changing the thickness of the oxide, the color reflected from the pattern can be changed, as described below in detail with reference to FIG. 6 and Table 1.

Although FIG. 1 illustrates an example where the printer head 116 moves in both X-direction and Y-direction while the substrate 112 remains stationary, in other embodiments, the printer head 116 may move in only X or Y direction while the substrate 112 is moved in Y or X direction. Alternatively, the printer head 116 may remain stationary while the substrate 112 is moved in both X and Y directions to form patterns on the substrate 112.

Further, a heater (not shown) may be provided below or near the substrate 112 to heat the substrate 112. The heating of the substrate 112 promotes the reaction between the source precursor and the reactant precursor to promote formation of a layer of material on the substrate 112.

In one embodiment, the printer head 116 is moved in the two-dimensional plane manually by operating personnel instead of using motors or other actuating mechanisms.

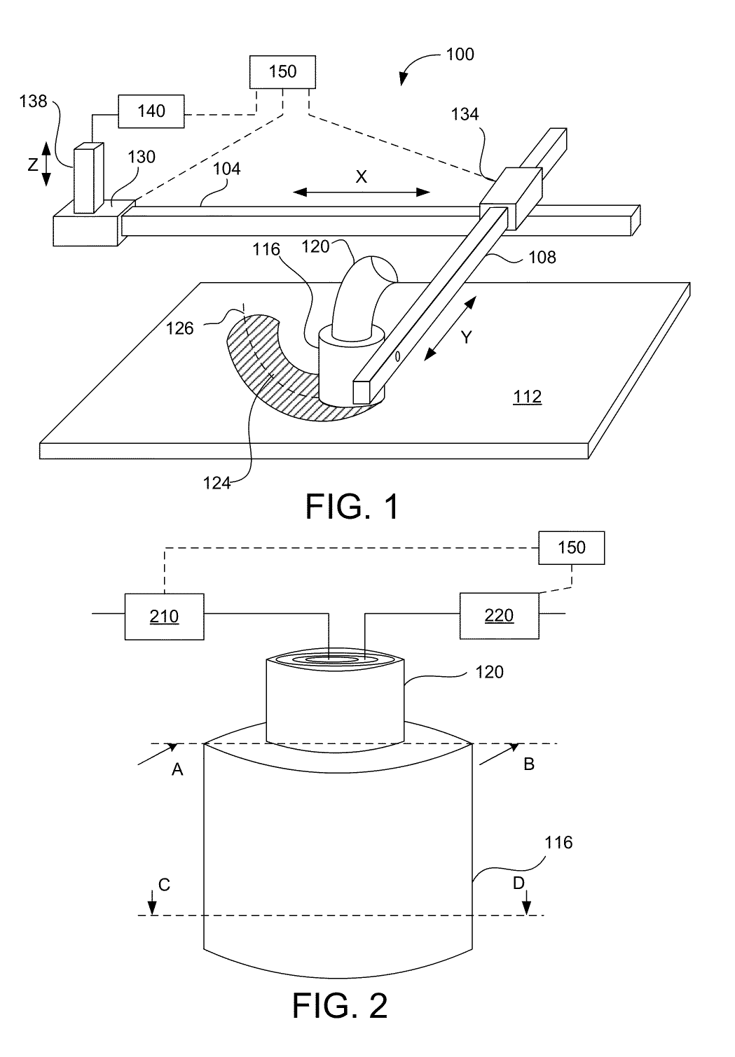

FIG. 2 is a perspective view of the printer head 116 and the conduit 120 for providing gas to the printer head 116, according to one embodiment. In the embodiment of FIG. 2, the printer head 116 has a cylindrical shape and is formed with chambers and channels for routing gases for injection or discharging excess gases from the substrate 112. The shape of the printer head 116 of FIG. 2 is merely illustrative and the printer head 116 may be in various other shapes (e.g., a rectangular column shape). The printer head 116 is kept at a predetermined height above the substrate but preferably does not come in touch with the substrate 112 to prevent damage to the material deposited on the substrate 112.

The conduit 120 is connected to sources of various gases via valves 210, 220. The valves 210, 220 can be switched on or off to selectively connect the conduit 120 to the sources of the gases. The valves 210, 220 may also be controlled to adjust the amount of gas provided to the printer head 116. When conduits are disconnected from the sources, the gases are no longer injected onto the substrate 112, and hence, no pattern is formed on the substrate 112. By shutting on or off the valves 210, 220, discontinuous line segments can be formed on the substrate 112 using the printer head 116. The operation of the valves 210, 220 may be controlled by the controller 150.

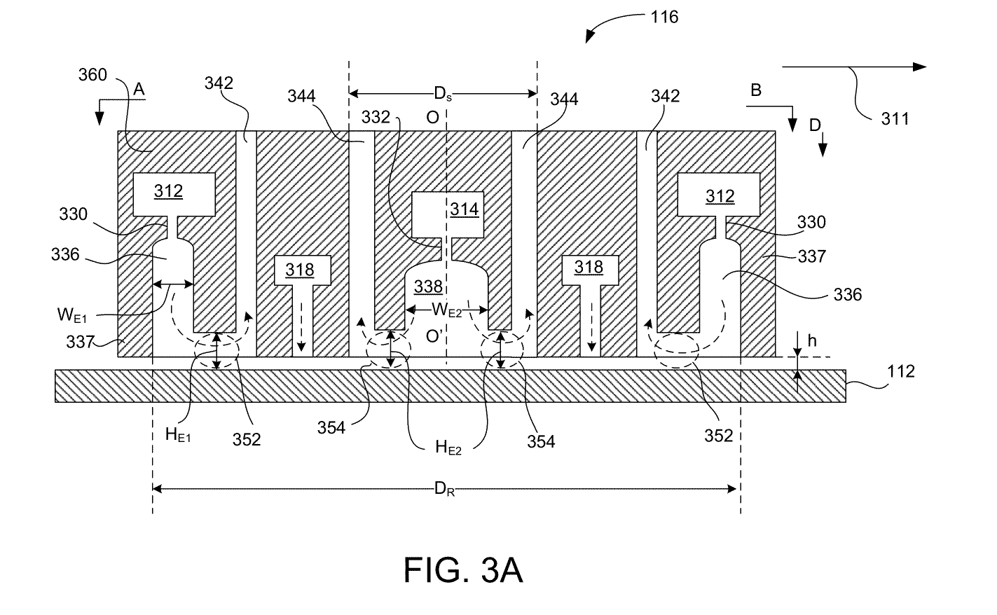

FIG. 3A is a cross sectional diagram of the printer head 116 taken along line A-B of FIG. 2, according to one embodiment. The bottom of the body 360 is separated from the top surface of the substrate 112 by a distance of h. The body 360 of the printer head 116 is formed with channels 312, 314, 318 to convey gases to the bottom of the printer head 116.

The channel 312 is formed in the outer periphery of the body 360. In one embodiment, the channel 312 carries reactant precursor gas received via the conduit 120. The reactant precursor gas may include radicals. The reactant precursor travels via perforations or slit 330 to an injection chamber 336 having a width of W_{E1}. The substrate 112 is injected with the reactant precursor below the injection chamber 336. As a result, the source precursor may react or replace source precursor adsorbed on the substrate 112 and form a layer of material on the substrate 112.

The reactant precursor moves through a constriction zone 352 and is discharged via an exhaust 342. The constriction zone 352 has a height H_{E1} that is smaller than the width W_{E1} of the injection chamber 336. In one embodiment, the height H_{E1} is from 1 mm to 4 mm. Due to the reduced size of passage in the constriction zone 352, the speed of the reactant precursor in the constriction zone 352 is increased while the pressure of the reactant precursor is decreased in the constriction zone 352 compared to the reactant precursor in the injection chamber 336. Thus, the flow of the reactant precursor through the constriction zone 352 facilitates the removal of excess reactant precursor (e.g., reactant precursor molecules physisorbed on the substrate 112) while leaving the deposited material intact on the substrate 112.

To cause sufficient Bernoulli effect in the constriction zone 352, the height H_{E1} of the constriction zone 352 is smaller than ⅔ of the width W_{E1}, and more preferably smaller than ⅓ of the diameter W_{E1}. The constriction zone 352 also enables the reactant precursor to form self-sustaining laminar flow to cause the reactant precursor to react or replace the source precursor in a uniform manner. The constriction zone 352 reduces leaking or diffusion of reactant precursor beyond outer wall 337 of the printer head 116 by facilitating discharge of the reactant precursor through the exhaust 342 due to pressure at the constriction zone 352 that is lower than the pressure gap (with height of h) between the outer wall 337 and the substrate 112. In some embodiments, outer wall 337 protrudes downwards and forms the outer periphery of the reactor 116 to reduce leaking or diffusion of reactant precursor. Whenever the printer head is moving, the printer head injects the reactant precursor on the substrate 112 across an area corresponding to an outer diameter of D_{R}.

The channel 314 is formed near center axis O—O′ of the printer head 116. In one embodiment, the channel 314 carries source precursor. The source precursor in the channel 314 is injected into an injection chamber 338 via a perforation 332. The injection chamber 338 has a diameter of W_{E2}. The portion of the substrate 112 below the injection chamber 338 is injected with the source precursor. Part of the injected source precursor is adsorbed on the substrate 112 while remaining excess source precursor is discharged via the constriction zone 354 to an exhaust 344. In some embodiments, some portions of excess source precursor may remain on the surface of the substrate for increasing the deposition rate of material on the substrate. The constriction zone 354 has a height H_{E2} that is smaller than the diameter W_{E2} of the injection chamber 338.

As a result, the pressure of the source precursor drops and the speed of the source precursor increases as the source precursor passes through the constriction zone 354, facilitating removal of excess source precursor (e.g., source precursor molecules physisorbed on the substrate 112) while leaving source precursor molecules chemisorbed on the substrate 112 intact.

To cause sufficient Bernoulli effect in the constriction zone 354, the height H_{E2} of the constriction zone 354 is smaller than ⅔ of the diameter W_{E2}, and more preferably smaller than ⅓ of the diameter W_{E2}. In one embodiment, the height H_{E2} is from 1 mm to 4 mm. The constriction zone 354 also enables the source precursor to form self-sustaining laminar flow to adsorb the source precursor in a uniform manner. When the printer head 116 moves on the substrate 112, an area with diameter Ds is exposed to the source precursor.

The remaining source precursor is discharged via the exhaust 344. In the example of FIG. 3A, a portion of the substrate having a diameter Ds is exposed to the source precursor when the printer head 116 and the substrate 112 remain stationary. The diameter Ds represents the smallest width of a pattern that can be formed on the substrate 112 using the printer head 116. A printer head with a larger diameter Ds will deposit a pattern with a thicker line feature covering a larger surface area of the substrate 112 whereas a printer head with a smaller diameter Ds will deposit a patter with a finer line feature covering a smaller surface area of the substrate 112.

The channel 318 carries separation gas (e.g., inert gas such as Argon). The separation gas forms an air curtain between the portion of the printer head 116 injecting the source precursor and the portion of the printer head 116 injecting the reactant precursor. In this way, the mixing of the source precursor and the reactant precursor is prevented from occurring at places other than on the substrate 112. Hence, formation of particles due to the reaction between source precursor and the reactant precursor can be prevented. Moreover, the separation gas also functions as purge gas that removes all or some of the physisorbed molecules of the source precursor or reactant precursor by controlling the flow rate of the purge gas while keeping at least chemisorbed molecules of the source precursor or reactant precursor intact on the substrate 112. Remaining physisorbed molecules on the substrate may increase the deposition rate of the material on the substrate 112.

As the printer head 116 moves over the substrate 112, a portion of the substrate 112 below the printer head 116 is exposed to a series of gas. Assuming that the printer head 116 moves in the direction identified by arrow 311, the substrate 112 below the printer head 116 is sequentially exposed to the reactant precursor, separation gas (purge gas), the source precursor, the separation gas and then the reactant precursor. That is, the area represented by diameter Ds is exposed to the source precursor, the purge gas and then the reactant precursor. As a result of the reaction between the source precursor and the reactant precursor, a layer of material in the form of a line feature is deposited on the substrate 112.

In one embodiment, the distance h is either a function of diameter Ds or may be set to a fixed value, for example, less than 1 mm. For example, the distance h is set to a value less than one tenth of Ds to minimize the precursor leak through this gap.

In one embodiment, the source precursor is Tris[dimethylamino]Silane (3DMAS) and the reactant precursor is O* or (OH)* radicals to deposit a SiO₂ film which is transparent in a visible spectrum. The reaction of such source precursor and the reactant precursor deposits a layer of SiO₂ on the substrate 112.

In other embodiments, O₃, H₂O, H₂O₂, N₂O plasma, O₂ plasma, (H₂+O₂) plasma, O₃ plasma, H₂O plasma or their combination may be used as reactant precursor for depositing an oxide layer on the substrate. NH₃, NH₂—NH₂, N₂ plasma, NH₃ plasma, (N₂+H₂) plasma, N* radical or their combination may be used as reactant precursor for depositing a nitride layer on the substrate. C₂H₂ plasma, CH₄ plasma, C₆H₆ plasma, (H₂+CH₄) plasma, C* radical or their combination may be used for depositing a carbonized layer, carbon nano-tube, graphine or graphine oxide on the substrate 112.

In other embodiments, the source precursors are either Tetrakis-dimethylamino Titanium (TDMAT) or titanium tetraisopropoxide (TTIP) for forming a TiO₂ film, and Tetrakis-ethylmethylamino Hafnium (TEMAHf) for forming a HfO₂ film which has a higher refractive indexed a SiO₂ film. The thicknesses of TiO₂ and HfO₂ films on this application may be thinner than the thickness of the SiO₂ film.

In other embodiments, the source precursor is injected via the channel 312 into the injection chamber 336 and the reactant precursor is injected via the channel 314 into the injection chamber 338. In these embodiments, excess reactant precursor is discharged via exhaust 344, and excess source precursor is discharged via exhaust 342.

FIG. 3B is a cross sectional diagram of the printer head 116 taken along line C-D of FIG. 2, according to one embodiment. The printer head 116 is formed with inlets 362 for receiving the reactant precursor, inlets 364 for receiving the separation gas, and an inlet 366 for receiving the source precursor. The reactant precursor, the separation gas and the source precursor are transferred to the channel 312, the channel 318 and the channel 314, respectively, via holes (not shown) formed in the body 360.

The body 360 of the printer head 116 is also formed with exhausts 342, 344 for discharging the excess reactant precursor and the excess source precursor, respectively. The exhausts 342, 344 are connected to the injection chambers 336, 338 via constriction zones 352 and 354.

Although the printer head 116 of FIGS. 3A and 3B is illustrated as being symmetric with respect to the axis O—O′, other embodiments may have non-symmetric shape or configuration.

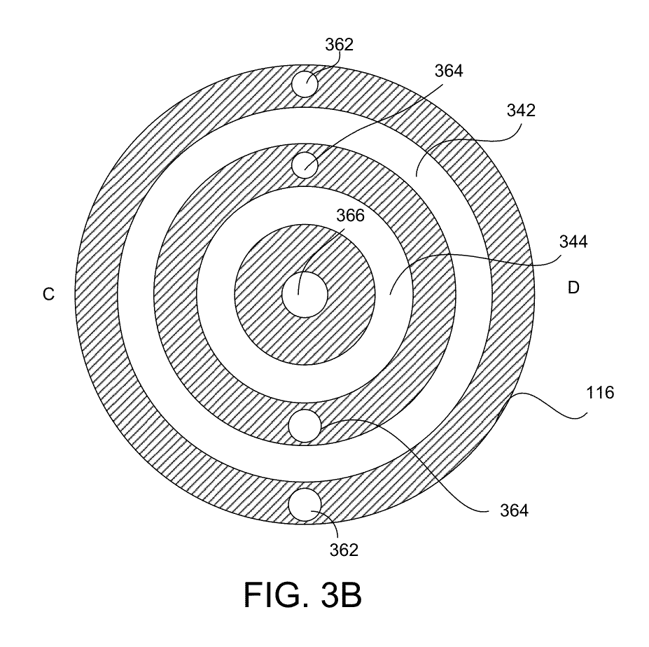

FIG. 4 is a sectional diagram of a printer head 400, according to another embodiment. The printer head 400 includes a first portion 410 and a second portion 420. The first portion 410 is identical to the printer head 116 of FIGS. 3A and 3B, and therefore, detailed description thereof is omitted herein for the sake of brevity. The printer head 400 further includes the second portion 420 for injecting purge gas (e.g., inert gas) through channel 422, perforations or slits 424, and an injection chamber 428. The gas in the injection chamber 428 is injected onto the substrate 112 to remove excess reactant precursor or other excess material from the surface of the substrate 112. In order to enhance the removal process, a constriction zone 438 having the height H_{E3} smaller than the width W_{E3} is formed in the printer head 400. As the purge gas moves through the constriction zone 438, the pressure of the purge gas drops and the speed of the purge gas increases due to Bernoulli effect. The purge gas and any excess material are discharged via exhaust 442.

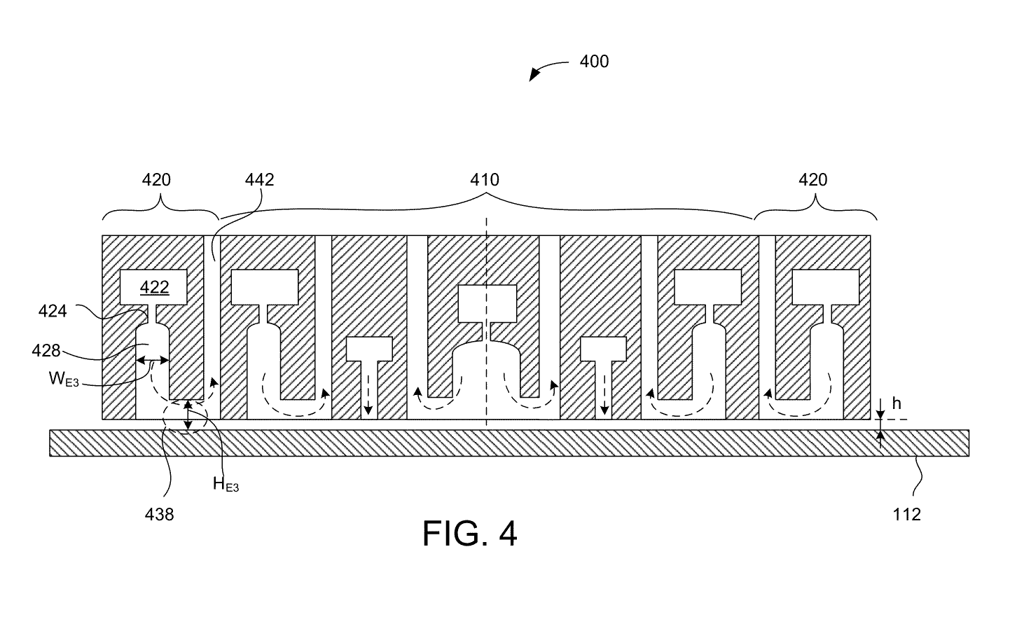

FIG. 5 is a top view of a substrate 112 printed with patterns 510, 520, 530, according to one embodiment. The patterns 510, 520, 530 are formed by moving the printer head 116 along a defined path while switching on or off valves 210, 220 for injecting precursor materials into the printer head 116.

Each of the patterns 510, 520, 530 may have different colors by varying the thickness of the material deposited on the substrate 112. FIG. 6 is a cross sectional diagram of substrate 112 printed with material 614, 618 of different thickness (t₁, t₂) to show different colors, according to one embodiment. By depositing a layer of transparent or semi-transparent material of a different thickness on the substrate 112, the color of the pattern can be changed due to different refractive characteristics of the deposited material. For example, when SiO₂ of 1000 Å is deposited, the pattern exhibits red-violet (color code: B32F79) color. When SiO₂ of 3450 Å is deposited, the pattern exhibits green (color code: 00FF00) color. When SiO₂ of 1250 Å is deposited, the pattern exhibits blue (color code: 0000FF) color. By using different combinations of colors, a holographic image in color can be patterned on the substrate.

The thickness of materials formed on the substrate 112 may be changed by one or more of the following ways. First, the printer head may move over the same path a number of times to deposit a thicker layer of material on the substrate. The color of the deposited material may be changed due to the thickness of the deposited material. Alternatively, the print head may move along a path with junction points or areas where the print head passes through multiple times. In such instance, the layer of material on the junction points or areas would be thicker than other portions of the path. Hence, the color of the deposited material at the junction points or areas will be different from other areas of the deposited material.

Second, the portions where the printer head moves at a higher speed are likely to be exposed to a less amount of source precursor and reactant precursor. Hence, a thinner layer of material is likely to be deposited along a path where the printer head moves at a higher speed. By controlling the moving speed of the printer head, a layer of different thickness may be deposited on the substrate, and hence, the color of the deposited material may be varied.

Third, the flow rate of the source precursor, the reactant precursor, the purge gas or a combination thereof may be controlled to deposit materials of different thickness on the substrate. For example, the valves 210, 220 may be controlled to inject these gases to the printer head at different rates. When the amount of gas injected into the printer head is decreased, the thickness of the deposited layer is also decreased, causing a change in the color of the deposited material.

Fourth, the concentration of the source precursor or reactant precursor in the gas injected into channel may be changed. When the concentration of the precursor relative to a carrier gas is higher, a thicker layer of material is likely to be formed on the substrate.

Fifth, when radicals are used to as source or reactant precursor, power source for generating radicals may be controlled to increase or decrease the reactivity of the precursor. The radicals may be generated using various ways such as exposing gas to ultra violet rays or generating plasma in a chamber filled with the gas. By controlling parameters associated with power (e.g., voltage level of electrodes for generating plasma), the reactivity of the radicals can be controlled. When the substrate is exposed to radicals of higher reactivity, a thicker layer of material forms on the substrate.

Sixth, different precursor material may be injected into the printer head to deposit material of different type or thickness on the substrate. Some precursor tends to deposit a thicker material than other precursors. Hence, by selectively feeding the type of precursor injected by the printer head, materials of different thickness may be formed on the substrate.

In some embodiments, a combination of above methods may be used to control the thickness of material deposited on the substrate. The controller 150 may be programmed to adjust one or more of parameters associated with the above methods to control the thickness of the deposited material.

Some of many advantages of using ALD to form patterns on the substrate are that the thickness of the deposited material can be tightly controlled, and that the material deposited by ALD is resistant to abrasion or discoloration due to exposure to ultraviolet rays or extreme ultra violet rays.

The following table shows examples of various colors that can be expressed by depositing SiO₂ of different thickness on a substrate.

TABLE 1

| Oxide | | |
|---|---|---|
| Thickness | COLOR | |
| [Å] | CODE | Color and Comments |
| 500 | D2B48C | Tan |
| 750 | A52A2A | Brown |
| 1000 | B32F79 | Dark Violet to red violet |
| 1250 | 2E73F3 | Royal blue |
| 1500 | ADD8E6 | Light blue to metallic blue |
| 1750 | D9ECB3 | Metallic to very light yellow-green |
| 2000 | F9F9C8 | Light gold or yellow slightly metallic |
| 2250 | DAA520 | Gold with slight yellow-orange |
| 2500 | F6853D | Orange to Melon |
| 2750 | B32F79 | Red-Violet |
| 3000 | 5D3694 | Blue to violet-blue |
| 3100 | 0000FF | Blue |
| 3250 | 0083AE | Blue to blue-green |
| 3450 | 00FF00 | Light green |
| 3500 | 84D82E | Green to yellow-green |
| 3650 | 84C82E | Yellow-green |
| 3750 | E2DE2B | Green-yellow |
| 3900 | FFFF00 | Yellow. |
| 4120 | FFB500 | Light orange |
| 4260 | FA7FC1 | Carnation pink |
| 4430 | E82362 | Violet-red |
| 4650 | B32F79 | Red-violet |
| 4760 | EE82EE | Violet |
| 4800 | 5D3694 | Blue Violet |
| 4930 | 0000FF | Blue |
| 5020 | 008080 | Blue-green |
| 5200 | 008846 | Green (Broad) |
| 5400 | 9ACD32 | Yellow-green |
| 5600 | ADFF2F | Green-yellow |
| 5740 | FFFFD2 | Yellow to Yellowish (not yellow but is in the |
| | | position where yellow is to be expected. At |
| | | times is appears to be light creamy gray or |
| | | metallic) |
| 5850 | FFDE93 | Light orange or yellow to pink borderline |
| 6000 | FA7FC1 | Carnation pink |
| 6300 | EE82EE | Violet-red |
| 6800 | AE82FF | Bluish (Not blue but borderline between violet |
| | | and blue-green. It appears more like a Mixture |
| | | between violet-red and blue-green and over-all |
| | | looks grayish) |
| 7200 | 00A080 | Blue-green to green (quite broad) |
| 7700 | FFFF8C | Yellowish |
| 8000 | FFA500 | Orange (rather broad for orange) |
| 8200 | FA8072 | Salmon |
| 8500 | B32F79 | Dull, light red-violet |
| 8600 | EE82EE | Violet |
| 8700 | 5D3694 | Blue-violet |
| 8900 | 0000FF | Blue |
| 9200 | 0083AE | Blue-green |
| 9500 | 84C82E | Dull yellow-green |
| 9700 | FFFF00 | Yellow to Yellowish |
| 9900 | F3770C | Orange |
| 10000 | FA7FC1 | Carnation Pink |
| 10200 | E82362 | Violet-red |
| 10500 | B32F79 | Red-violet |
| 10600 | EE82EE | Violet |
| 10700 | 5D3694 | Blue-violet |
| 11000 | 008846 | Green |
| 11100 | 84C82E | Yellow-green |
| 11200 | 008846 | Green |
| 11800 | EE82EE | Violet |
| 11900 | B32F79 | Red-violet |
| 12100 | E82362 | Violet-red |
| 12400 | FA7FA1 | Carnation Pink-Salmon |
| 12500 | FFA500 | Orange |
| 12800 | FFFF00 | Yellowish |
| 13200 | 47B0E3 | Sky blue to green-blue |
| 14000 | FFA500 | Orange |
| 14500 | EE82EE | Violet |
| 14500 | 5D3694 | Blue-violet |
| 15000 | 0000FF | Blue |
| 15100 | 84C82E | Dull Yellow-green |

In order to exhibit colors not shown in the above table, segments of the substrate may be deposited with materials with different thicknesses. Each segment of the substrate will reflect different colors, and the combined reflection of from the segments will result in a color different from the color reflected by individual segments.

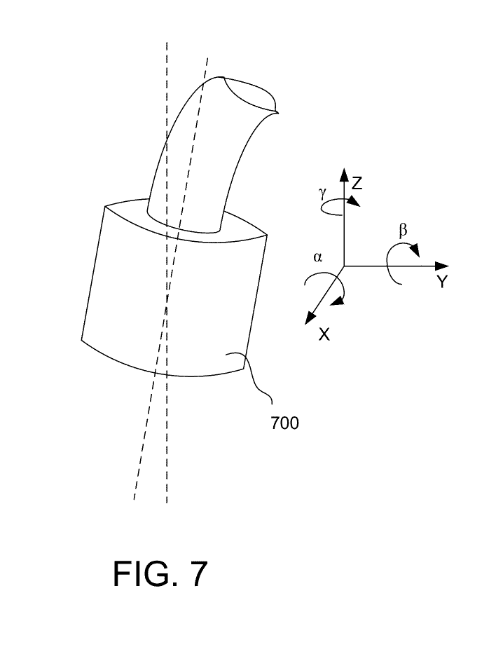

FIG. 7 is a schematic diagram illustrating the degree of freedom for the printer head 700 according to one embodiment. Although the printer head 116 of FIG. 1 has three degrees of freedom (X, Y and Z-directions), other embodiments may include printer heads with more or less degrees of freedom. For example, the printer head 700 may have six degrees of freedom by capable of linear movements in X, Y and Z-directions, and rotation in α, β and γ angles. With increased degrees of freedom, the printer head 700 can deposit materials on non-planar surfaces (e.g., curved surfaces). Mechanisms for moving or rotating the printer head 700 may include actuators such as motors, links or hydraulic devices.

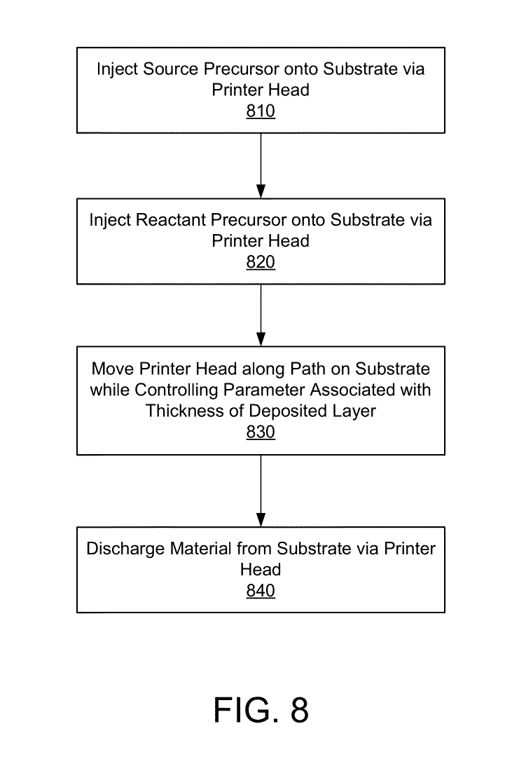

FIG. 8 is a flowchart illustrating a method of forming a pattern of material with different thickness, according to one embodiment. Source precursor is injected 810 onto a substrate via printer head 116. Reactant precursor is also injected 820 onto a substrate via printer head 116. The source precursor and the reactant precursor may be injected into the printer head via valves 210, 220 and conduit 120.

Printer head 116 moves along a path on the substrate while controlling one or more parameters associated with the thickness of material deposited on the substrate. The path of the printer head 116 may include straight lines, curves and random shapes. The one or more parameters includes one or more of the following: (i) the speed at which the printer head 116 is moving, (ii) the amount or concentration of source precursor and/or reactant precursor injected into the printer head 116 and (iii) the reactivity of radicals used as source precursor or reactant precursor. By changing these parameters, the thickness of the material deposited on the substrate may be changed, causing different portions of the pattern to exhibit different colors.

Excess material is discharged 840 from the substrate by the printer head 116, for example, by injecting purge gas onto the substrate. The excess material may include, source precursor, reactant precursor and material deposited on the substrate but not chemisorbed on the substrate. The excess material may be discharged using exhausts 342, 344.

The sequence of processes illustrated in FIG. 8 is merely illustrative. Although steps 810 through 840 are illustrated as being performed sequentially, these steps may be performed simultaneously. Additional steps such as injecting purge gas which not illustrated in FIG. 8 may also be performed.

Although the present invention has been described above with respect to several embodiments, various modifications can be made within the scope of the present invention. Accordingly, the disclosure of the present invention is intended to be illustrative, but not limiting, of the scope of the invention.

1. An apparatus for printing a pattern on a substrate, comprising:
a printer head configured to inject source precursor and reactant precursor onto the substrate to deposit a layer of material forming the pattern by atomic layer deposition;
a first actuator causing a surface of the printer head to move along a first axis parallel to a surface of the substrate;
a second actuator causing the surface of the printer head to move along a second axis parallel to the surface of the substrate; and
a conduit connected to the printer head, the conduit providing the source precursor and the reactant precursor to the printer head.

2. The apparatus of claim 1, further comprising a controller configured to control at least a parameter associated with a thickness of the layer of the material deposited on the substrate.

3. The apparatus of claim 2, wherein different portions of the pattern exhibit different colors based on the different thickness of the layer of material.

4. The apparatus of claim 1, further comprising a third actuator causing the printer head to move towards or away from the substrate.

5. The apparatus of claim 1, wherein the printer head is further configured to inject purge gas onto the substrate to remove at least excess source precursor from the surface of the substrate, the purge gas provided by the conduit.

6. The apparatus of claim 1, wherein the printer head comprises a body formed with a first injection chamber for injecting the source precursor onto the substrate, and a second injection chamber surrounding the first injection chamber for injecting the reactant precursor onto the substrate.

7. The apparatus of claim 6, wherein the body is further formed with:
a channel open towards the substrate to inject purge gas onto the substrate, the channel formed between the first injection chamber and the second injection chamber;
a first exhaust formed between the first injection chamber and the channel to discharge excess source precursor not chemisorbed on the substrate; and
a second exhaust formed between the channel and the second injection chamber to discharge at least excess reactant precursor not chemisorbed on the substrate.

8. The apparatus of claim 7, wherein the body is formed with:
a first constriction zone is formed between the first exhaust and the first injection chamber, the first constriction zone having a height smaller than a width of the first injection chamber; and
a second constriction zone formed between the second exhaust and the second injection chamber, the second constriction zone having a height smaller than a width of the second injection chamber.

9. A printer head assembly comprising:
a printer head comprising a body formed with:
a first injection chamber for injecting first gas onto a substrate, and
a second injection chamber surrounding the first injection chamber, the second injection chamber configured to inject second gas onto the substrate, the second gas reacting or replacing molecules of the first gas adsorbed on the substrate to form a layer of material on the substrate; and
a conduit connected to the printer head to provide the first gas and the second gas to the printer head.

10. The printer head assembly of claim 9, wherein the body is further formed with:
a channel open towards the substrate to inject purge gas onto the substrate, the channel formed between the first injection chamber and the second injection chamber;
a first exhaust formed between the first injection chamber and the channel to discharge excess first precursor not chemisorbed on the substrate; and
a second exhaust formed between the channel and the second injection chamber to discharge at least excess second precursor not chemisorbed on the substrate.

11. The printer head assembly of claim 10, wherein the body is further formed with:
a first constriction zone is formed between the first exhaust and the first injection chamber, the first constriction zone having a height smaller than a width of the first injection chamber; and
a second constriction zone formed between the second exhaust and the second injection chamber, the second constriction zone having a height smaller than a width of the second injection chamber.

12. A method of forming a pattern on a substrate, comprising:
injecting source precursor onto a surface of a substrate via a printer head;
injecting reactant precursor onto the surface via the printer head;
moving the printer head along a path on a substrate while controlling at least a parameter associated with a thickness of layer deposited on the substrate by reaction or replacement of molecules of the source precursor with molecules of the reactant precursor on the surface; and
discharging excess source precursor and reactant precursor from the surface of the substrate via the printer head.

13. The method of claim 12, further comprising injecting purge gas onto the surface via the printer head to remove excess source precursor from the surface of the substrate.

14. The method of claim 12, wherein the parameter comprises at least one of (i) a speed of the printer head traveling over the surface of the substrate, (ii) an amount or concentration of the source precursor or the reactant precursor provided to the printer head or (iii) reactivity of radicals provided to the printer head as the source precursor or the reactant precursor.

15. The method of claim 12, wherein the path overlaps at junction points or junction areas on the surface of the substrate to deposit a thicker material on the junction points or junction areas.

16. The method of claim 12, further comprising moving the printer head towards or away from the surface of the substrate.

17. The method of claim 12, further comprising:
injecting purge gas onto the printer head via a channel formed in the printer head;
discharging excess source precursor not chemisorbed on the substrate via a first constriction zone connecting a first injection zone for injecting the source precursor to the surface of the substrate to a first exhaust; and
discharging excess reactant precursor not chemisorbed on the substrate via a second constriction zone connecting a second injection zone for injecting the reactant precursor to the surface of the substrate to a second exhaust.
